(19) United States
(12) Patent Application Publication
(10) Pub. No.: US 2025/0258433 A1
(43) Pub. Date: Aug. 14, 2025

(54) UNDERLAYER TREATMENT FOR IMPROVED PHOTORESIST ADHESION

(71) Applicant: Applied Materials, Inc., Santa Clara, CA (US)

(72) Inventors: Sudha RATHI, San Jose, CA (US); Unnati JOSHI, Fremont, CA (US); Nancy FUNG, Livermore, CA (US); Pramit MANNA, Santa Clara, CA (US); Karthik JANAKIRAMAN, San Jose, CA (US)

(21) Appl. No.: 19/051,734

(22) Filed: Feb. 12, 2025

Related U.S. Application Data
(60) Provisional application No. 63/552,532, filed on Feb. 12, 2024.

(51) Int. Cl. G03F 7/09; G03F 1/24; G03F 1/38; G03F 7/11; G03F 7/20; H01L 21/027

(52) U.S. Cl. CPC G03F 7/094; G03F 1/24; G03F 1/38; G03F 7/11; G03F 7/2004; H01L 21/0274

(57) ABSTRACT

The present disclosure generally relates to the fabrication of integrated circuits. More particularly, embodiments described herein provide techniques for forming resist underlayers having reduced sp2 hybridized carbon content for improving EUV lithography performance. In one embodiment, a method of processing a substrate is provided. The method includes flowing a resist underlayer gas mixture into a process chamber having a substrate and generating a plasma in the process chamber by applying a first RF bias for forming a resist underlayer on the substrate.

### CROSS-REFERENCE TO RELATED APPLICATIONS

This application claims the benefit of U.S. Provisional Patent Application Ser. No. 63/552,532, filed Feb. 12, 2024, which is incorporated by reference herein in its entirety.

### BACKGROUND

### Field

Embodiments of the present disclosure generally relate to the field of semiconductor processing and, in particular, to methods of fabricating integrated circuits using extreme ultraviolet (EUV) lithography.

### Description of the Related Art

Integrated circuits have evolved into complex devices that can include millions of transistors, capacitors and resistors on a single chip. The evolution of chip designs continually requires faster circuitry and greater circuit density. The demands for faster circuits with greater circuit densities impose corresponding demands on the materials used to fabricate such integrated circuits. In particular, as the dimensions of integrated circuit components reduce to the sub-micron scale, it is now necessary to use low resistivity conductive materials as well as low dielectric constant insulating materials to obtain suitable electrical performance from such components. 0

As pattern dimensions are reduced, extreme ultraviolet (EUV) exposure is expected to be the method of choice for single exposure lithography to achieve required critical dimension (CD) targets in the sub 20-nm region and beyond. EUV lithography uses a far smaller wavelength than the 193 nm wavelengths of the conventional techniques to scale down the feature sizes on the IC chips. Typically, EUV lithography uses a EUV wavelength that is about 13.5 nm for patterning a EUV photoresist. The EUV resist, however, is much less resistant to etching than the photoresist used for conventional patterning techniques. As such, to use EUV lithography to form features on a substrate, a resist underlayer is typically deposited between the substrate and EUV photoresist.

The EUV lithography processes described above may suffer from several drawbacks. As the feature size of devices decrease, the resist underlayer may preferably be thinner to allow the formation of etched features with a desired resolution or critical dimension. However, as device dimensions shrink, capillary forces due to the small feature size may cause pattern collapse during the development and cleaning processes which in turn prevents the use of the patterned features of the photoresist for pattern transfer. Pattern collapse is caused by unbalanced capillary forces present during the final drying step of the standard lithographic process. Generally, the main cause for pattern collapse are the capillary forces present at the resist surface after the resist is developed and rinsed in a wet development process. Pattern collapse may occur either due to bending or breaking of the patterned photoresist structures. However, one of the primary modes of pattern collapse is adhesion failure at the resist-substrate interface resulting in the delamination of the photoresist structure from the substrate surface.

To enable further miniaturization of resist pattern transfer for EUV lithography, addressing pattern collapse and etch resistance of the resist are important. Accordingly, there is a need in the art for improving adhesion force between the resist underlayer and photoresist.

### SUMMARY

Embodiments of the present disclosure generally relate to the fabrication of integrated circuits. More particularly, the embodiments described herein provide techniques for modifying a surface of a resist underlayer for improving adhesion with a EUV photoresist disposed thereon. In one embodiment, a method of processing a substrate is provided . . .

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 depicts a schematic cross-sectional view of a process chamber that can be used for the practice of the method of the present disclosure, according to certain embodiments described herein;

FIG. 2 is a schematic block diagram of a method of substrate processing, according to certain embodiments described herein;

FIGS. 3A-3D are partial schematic cross-sectional views of a substrate during the method of substrate processing in FIG. 3, according to certain embodiments; and

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Methods of forming a resist underlayer for use in EUV lithography processes is described herein. In the following description, numerous specific details are set forth in order to provide a thorough understanding of embodiments of the present disclosure. It will be apparent to one skilled in the art that embodiments of the present disclosure may be practiced without these specific details. In other instances, well-known aspects, such as integrated circuit fabrication, are not described in detail in order to not unnecessarily obscure embodiments of the present disclosure. Furthermore, it is to be understood that the various embodiments shown in the Figures are illustrative representations and are not necessarily drawn to scale.

Embodiments described herein will be described below in reference to a PECVD process that can be carried out using any suitable thin film deposition system. Examples of suitable systems include the CENTURA® systems which may use a DXZ® processing chamber, PRECISION 5000® systems, PRODUCER® systems, PRODUCER® GT™ systems, PRODUCER® XP Precision™ systems, PRODUCER® SE™ systems, Sym3® processing chamber, and Mesa™ processing chamber, all of which are commercially available from Applied Materials, Inc., of Santa Clara, Calif. Other tools capable of performing PECVD processes may also be adapted to benefit from the embodiments described herein. In addition, any system enabling the PECVD processes described herein can be used to advantage. The apparatus description described herein is illustrative and should not be construed or interpreted as limiting the scope of the embodiments described herein.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface.

As used herein, “extreme UV”, “EUV”, or the like, refers to radiation in the approximate range of 10 nm to 124 nm. In some embodiments, EUV radiation (also referred to as EUV light) in the range of 10 nm to 15 nm. In one or more embodiments, EUV light at a wavelength of about 13.5 nm is employed.

Although the following discusses the application in which the resist underlayer is disposed directly on the substrate, it will be appreciated that in some embodiments, there may be one or more intermediate layers applied to the substrate first. In such instances, the resist underlayer can then be applied to the upper most intermediate layer rather than to the substrate surface. Examples of possible intermediate layers that could be utilized include those selected from the group consisting of hard masks (including spin-on carbon), organic layers, carbon layers, organo-metallic layers, and barrier layers.

In EUV photolithography, the demand for ever-decreasing feature sizes has also led to the use of thinner films to prevent pattern collapse. As feature and device sizes decrease, the stack thickness is correspondingly reduced. Accordingly, the thickness of the energy sensitive EUV photoresist may correspondingly be reduced in order to control pattern resolution. As such, the resist underlayer may preferably also be thinner (e.g., 10 A-50 A) to allow the formation of etched features with a desired resolution and/or aspect ratio. However, as the thickness of the underlayer resist film decreases, the adhesion at the interface between the substrate surface (e.g., the resist underlayer) and the overlying EUV photoresist can decrease due to mis-matched surface energies between the two materials. Poor adhesion between the resist underlayer and the EUV photoresist can result in pattern collapse and/or other collapse induced lithography defects such as poor line width roughness (LWR).

High aspect ratio patterns are also increasingly being utilized to improve resist roughness performance and provide more etch resistance to allow a wider margin of etch transfer. However, increasing aspect ratio also give rise to an increased tendency for pattern collapse. This is particularly the case for patterning and etching of submicron pillars, for example for use in a memory array. Even at very small critical dimensions (CDs), photoresist line and space structures are generally mechanically strong enough to survive the exposure, development, and the cleaning and drying process that follows before the etch is performed. However, at the same CDs, photoresist pillars have less mechanical strength and are more likely to collapse before the etch can be performed.

Accordingly, embodiments of the present disclosure described herein include methods of fabricating and treating a resist underlayer to form a surface termination layer on the resist underlayer thereby increasing adhesion force with an overlying EUV photoresist subsequently disposed thereon.

EUV lithography process performance is determined based on its resolution, line width roughness (LWR), and sensitivity. LWR is a measure of the variation of the width of the lines formed by the lithography process. LWR reflect linewidth fluctuations that may lead to variations in device characteristics. As CD for integrated circuits continued to shrink, linewidth fluctuations may therefore play an increasingly significant role in CD error budget for lithography. Sensitivity can be further defined by the amount of energy or dose, needed to reach a certain feature size—sometimes also referred to as dose to size (DTS) ratio. Sensitivity of the EUV photoresist therefore also refers to the minimum dose of energy necessary to image the EUV photoresist. In some embodiments, advantages of the present disclosure also provides for increased depth of focus, increased process window (area with no pattern collapse) of the substrate surface, extended resolution limit/minimum CD of the pillar patterned photoresist without comprising CD uniformity, and improved sensitivity (lower DTS ratio). Improved sensitivity for EUV photoresists provide for decreased exposure time and thus, a lower DTS ratio, which in turn translates to increased efficiency of the process and throughput.

Aspects of the present disclosure may be used to tune surface properties of the resist underlayer, such as the surface energy of the resist underlayer, to promote increased adhesion with an overlying photoresist. Surface energy of the resist underlayer may be categorized into a polar part and a dispersive part of surface energy. The polar and dispersive parts of surface energy can be calculated by measuring a contact angle of a liquid, such as water, and using the Owens, Wendt, Rabel and Kaelble (OWRK) methods to determine the polar part and the dispersive part of the surface energy. In some embodiments, when used with suitable photoresists, improved adhesion between the resist underlayer and overlying photoresist offers improved process windows against pattern collapse, as well as improved LWR.

In some embodiments, the resist underlayer may be treated to form a surface termination layer used to alter and obtain a desired interfacial surface energy on the substrate surface. Exemplary surface termination layers can include silicon (Si), boron (B), nitrogen (N), tungsten (W), germanium (Ge), tin (Sn), or lead (Pb).

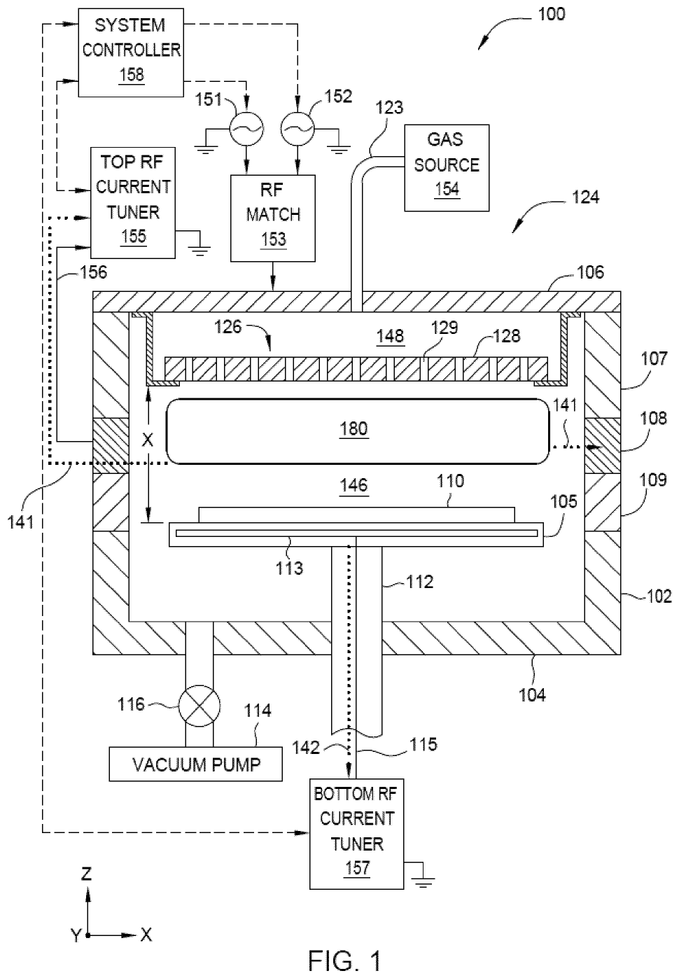

FIG. 1 is a schematic illustration of a cross sectional view of a process chamber 100 that can be used to form and treat a resist underlayer on a substrate prior to forming a patterned photoresist thereon, in accordance with embodiments described herein. By way of example, the embodiment of the process chamber 100 in FIG. 1 is described in terms of a PECVD system, but any other process chamber may fall within the scope of the embodiments, including other vapor deposition chambers or plasma deposition chambers. The process chamber 100 includes walls 102, a bottom 104, and a chamber lid 124 that together enclose a substrate support 105 and a processing volume 146. The process chamber 100 further includes a vacuum pump 114, a first RF generator 151, a second RF generator 152, an RF match 153, a gas source 154, a top RF current tuner 155, a bottom RF current tuner 157, and a system controller 158, each coupled externally to the process chamber 100 as shown.

The walls 102 and the bottom 104 may comprise an electrically conductive material, such as aluminum or stainless steel. Through one or more of the walls 102, a slit valve opening may be present that is configured to facilitate insertion of a substrate 110 into and removal of the substrate 110 from the process chamber 100. A slit valve configured to seal slit valve opening may be disposed either inside or outside of the process chamber 100. For clarity, no slit valve or slit valve opening is shown in FIG. 1.

The vacuum pump 114 is coupled to the process chamber 100 and is configured to adjust the vacuum level therein. As shown, a valve 116 may be coupled between the process chamber 100 and the vacuum pump 114. The vacuum pump 114 evacuates the process chamber 100 prior to substrate processing and removes process gas therefrom during processing through the valve 116. The valve 116 may be adjustable to facilitate regulation of the evacuation rate of the process chamber 100. The evacuation rate through the valve 116 and the incoming gas flow rate from the gas source 154 determine chamber pressure and process gas residency time in the process chamber 100.

The gas source 154 is coupled to the process chamber 100 via a tube 123 that passes through the chamber lid 124. The tube 123 is fluidly coupled to a plenum 148 between a backing plate 106 and a gas distribution showerhead 128 included in the chamber lid 124. During operation, process gas introduced into the process chamber 100 from the gas source 154 fills the plenum 148 and then passes through the gas passages 129 formed in the gas distribution showerhead 128 to uniformly enter the processing volume 146. In alternative embodiments, process gas may be introduced into the processing volume 146 via inlets and/or nozzles (not shown) that are attached to the walls 102 in addition to or in lieu of the gas distribution showerhead 128.

The substrate support 105 may include any technically feasible apparatus for supporting a substrate during processing by the process chamber 100, such as the substrate 110 in FIG. 1. In some embodiments, the substrate support 105 is disposed on a shaft 112 that is configured to raise and lower the substrate support 105. In one embodiment, the shaft 112 and the substrate support 105 may be formed at least in part from or contain an electrically conductive material, such as tungsten, copper, molybdenum, aluminum, or stainless steel. Alternatively or additionally, the substrate support 105 may be formed at least in part from or contain a ceramic material, such as aluminum oxide (Al₂O₃), aluminum nitride (AlN), silicon dioxide (SiO₂), and the like.

In some embodiments, the substrate support 105 may include a heater element (not shown) suitable for controlling the temperature of the substrate 110 supported on the top surface of the substrate support 105. The heater element 170 may be embedded in the substrate support 105. The substrate support 105 may be resistively heated by applying an electric current from a heater power source (not shown) to the heater element. The electric current supplied from the heater power source may also be regulated by the controller 158 to control the heat generated by the heater element, thus maintaining the substrate 110 and the substrate support 105 at a substantially constant temperature during film deposition. The supplied electric current may be adjusted to selectively control the temperature of the substrate support 105 or the substrate 110 disposed thereon between about −50 degrees Celsius to about 600 degrees Celsius.

In embodiments in which the process chamber 100 is a capacitively coupled plasma chamber, the substrate support 105 may be configured to contain an electrode 113. In such embodiments, a metal rod 115 or other conductor is electrically coupled to the electrode 113 and is configured to provide a portion of a ground path for RF power delivered to the process chamber 100. That is, the metal rod 115 enables a RF power delivered to the process chamber 100 to pass through the electrode 113 and out of the process chamber 100 to ground. Together, the electrode 113 and the gas distribution showerhead 128 define the boundaries of the processing volume 146 in which plasma is formed. For example, during processing, the substrate support 105 and the substrate 110 may be raised and positioned closer to the lower surface of the gas distribution showerhead 128 to form the at least partially enclosed processing volume 146.

In some embodiments, the electrode 113 may also be configured to provide an electrical bias from a DC power source (not shown) to enable electrostatic clamping of the substrate 110 onto the substrate support 105 during plasma processing. In such embodiments, the substrate support 105 may also be an electrostatic chuck that generally includes a body comprising one or more ceramic materials suitable for use in a substrate support. In such embodiments, the electrode 113 may be a mesh, such as an RF mesh, or a perforated sheet of material made of molybdenum (Mo), tungsten (W), or other material with a coefficient of thermal expansion that is substantially similar to that of the ceramic material or materials included in the body of the substrate support 105.

The first RF generator 151 is a radio frequency (RF) power source configured to provide high-frequency power at a first RF frequency to a discharge electrode 126 via the RF match 153. Similarly, the second RF generator 152 is an RF power source configured to provide RF power at a second RF frequency to the discharge electrode 126 via RF match 153. In some embodiments, first RF generator 151 includes an RF power supply capable of generating RF currents at a high frequency (HF), for example, about 13.56 MHz. Alternatively or additionally, the first RF generator 151 includes a VHF generator capable of generating VHF power, such as VHF power at frequencies between about 20 MHz to 200 MHz or more, such as about 27 MHz or about 40 MHz. By contrast, the second RF generator 152 includes an RF power supply capable of generating RF currents at so-called low frequency (LF) RF, for example, about 350 kHz. Alternatively or additionally, the second RF generator 152 includes an RF generator capable of generating RF power at frequencies between about 1 kHz and about 1 MHz. The first RF generator 151 and the second RF generator 152 are configured to facilitate generation of a plasma in the processing volume 146 between the discharge electrode 126 and the substrate support 105.

The discharge electrode 126 may include a process gas distribution element, such as the gas distribution showerhead 128 (as shown in FIG. 1), and/or an array of gas injection nozzles, through which process gases are introduced into the processing volume 146. The discharge electrode 126, i.e., the gas distribution showerhead 128, may be oriented substantially parallel to the surface of the substrate 110, and capacitively couples plasma source power into the processing volume 146, which is disposed between the substrate 110 and the gas distribution showerhead 128.

The RF match 153 may be any technically feasible impedance matching apparatus that is coupled between the first RF generator 151 and the powered electrode of the process chamber 100, i.e., the gas distribution showerhead 128. The RF match 153 is also coupled between the second RF generator 152 and the powered electrode of the process chamber 100. The RF match 153 is configured to match a load impedance (the process chamber 100) to the source or internal impedance of a driving source (the first RF generator 151, the second RF generator 152) to enable the maximum transfer of RF power from the first RF generator 151 and the second RF generator 152 to the process chamber 100.

Forming a portion of the walls 102 are an upper isolator 107, a tuning ring 108, and a lower isolator 109. The upper isolator 107 is configured to electrically isolate the tuning ring 108, which is formed from an electrically conductive material, from the backing plate 106, which in some embodiments is energized with RF power during operation. Thus, upper isolator 107 is positioned between the backing plate 106 and the tuning ring 108, and prevents the tuning ring 108 from being energized with RF power via the backing plate 106. In some embodiments, the upper isolator 107 is configured as a ceramic ring or annulus that is positioned concentrically about the processing volume 146. Similarly, the lower isolator 109 is configured to electrically isolate the tuning ring 108 from the walls 102. The walls 102 are typically formed from an electrically conductive material, and can therefore act as a ground path for a portion of RF power delivered to the process chamber 100 during processing. Thus, the lower isolator 109 enables the tuning ring 108 to be part of a different ground path for RF power delivered to the process chamber 100 than that of the walls 102. In some embodiments, the upper isolator 107 is configured as a ceramic ring, or is configured to include a ceramic ring that is positioned concentrically about the processing volume 146.

The tuning ring 108 is disposed between the upper isolator 107 and the lower isolator 109, is formed from an electrically conductive material, and is disposed adjacent the processing volume 146. For example, in some embodiments, the tuning ring 108 is formed from a suitable metal, such as aluminum, copper, titanium, or stainless steel. In some embodiments, the tuning ring 108 is a metallic ring or annulus that is positioned concentrically about the substrate support 105 and the substrate 110 during processing of the substrate 110. In addition, the tuning ring 108 is electrically coupled to ground via the top RF current tuner 155 via a conductor 156, as shown. Thus, the tuning ring 108 is not a powered electrode, and is generally disposed outside of and around the processing volume 146. In one example, the tuning ring 108 is positioned in a plane substantially parallel with the substrate 110, and is part of a ground path for the RF energy used to form a plasma in the processing volume 146. As a result, an additional RF ground path 141 is established between the gas distribution showerhead 128 and ground, via the top RF current tuner 155. Thus, by changing the impedance of the top RF current tuner 155 at a particular frequency, the impedance for the RF ground path 141 at that particular frequency changes, causing a change in the RF field that is coupled to the tuning ring 108 at that frequency. Therefore, the shape of plasma in the processing volume 146 may be independently modulated along the +/−X and Y-directions for the RF frequency associated with either the first RF generator 151 or the second RF generator 152. That is, the shape, volume or uniformity of the plasma formed in the processing volume 146 may be independently modulated for multiple RF frequencies across the surface of the substrate 110 by use, for example, of the tuning ring 108 or vertically between the substrate 110 and the gas distribution showerhead 128 using the electrode 113.

The system controller 158 is configured to control the components and functions of the process chamber 100, such as the vacuum pump 114, the first RF generator 151, the second RF generator 152, the RF match 153, the gas source 154, the top RF current tuner 155, and the bottom RF current tuner 157. As such, the system controller 158 receives sensor inputs, e.g., voltage-current inputs from the top RF current tuner 155 and the bottom RF current tuner 157, and transmits control outputs for operation of the process chamber 100. The functionality of the system controller 158 may include any technically feasible embodiment, including via software, hardware, and/or firmware, and may be divided between multiple separate controllers associated with the process chamber 100.

The top RF current tuner 155, as noted above, is electrically coupled to the tuning ring 108 and is terminated to ground, thus providing a controllable RF ground path 141 for the process chamber 100. Similarly, the bottom RF current tuner 157 is electrically coupled to the metal rod 115 and is terminated to ground, thus providing a different controllable RF ground path 142 for the process chamber 100. As described herein, the top RF current tuner 155 and the bottom RF current tuner 157 are each configured to control the flow of RF current to ground at multiple RF frequencies. Thus, the distribution of RF current at a first RF frequency between the tuning ring 108 and the metal rod 115 can be controlled independently from the distribution of RF current at a second RF frequency between the tuning ring 108 and the metal rod 115.

A plasma 180 is formed in the processing volume 146 in between the electrode 113 and the discharge electrode 126. A distance or “spacing” between the bottom surface of the electrode 113 and a top surface of the substrate support 105 is represented by “x”.

Other deposition chambers may also benefit from the present disclosure and the parameters listed above may vary according to the particular deposition chamber used to form the amorphous carbon layer. For example, other deposition chambers may have a larger or smaller volume, requiring gas flow rates that are larger or smaller than those recited for deposition chambers available from Applied Materials, Inc. In one embodiment, carbon gapfill layer may be deposited using a PRODUCER® XP Precision™ processing system, which is commercially available from Applied Materials, Inc., Santa Clara, California.

Proper control and regulation of the gas flows from the gas source 154 may be performed by mass flow controllers (not shown) and the controller 158. The gas distribution showerhead 128 allows process gases from the gas source 154 to be uniformly distributed and introduced into the processing volume 146.

The first RF generator 151 and the second RF generator 152 may produce power at the same frequency or a different frequency. In some embodiments, one or both of the first RF generator 151 and the second RF generator 152 may independently produce power at a frequency from about 350 KHz to about 100 MHz (e.g., 350 KHz, 2 MHz, 13.56 MHz, 27 MHz, 40 MHz, 60 MHz, or 100 MHz). In some embodiments, the first RF generator 151 may produce power at a frequency of 13.56 MHz and the second RF generator 152 may produce power at a frequency of 2 MHz, or vice versa. RF power from one or both of the first RF generator 151 and second RF generator 152 may be varied in order to tune the generated plasma.

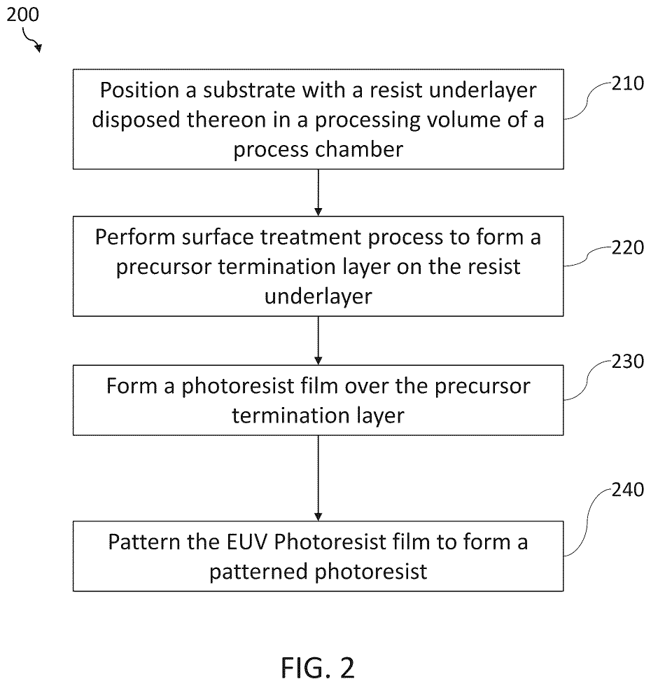

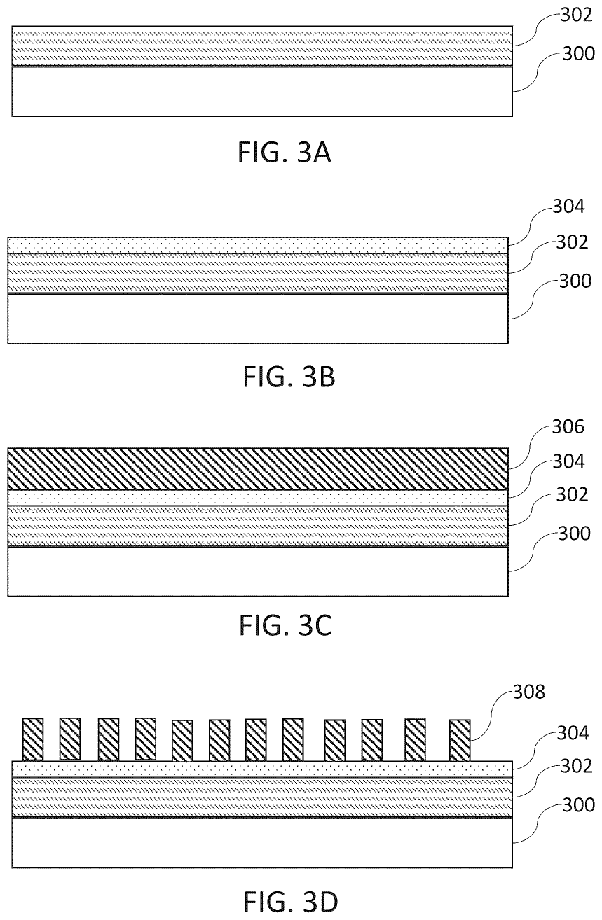

FIG. 2 is a schematic block diagram of a method 200 for processing a resist underlayer disposed on a substrate, according to certain embodiments described herein. FIGS. 3A-3D are partial schematic side cross-sectional views of a substrate 300 during the method 200, according to one or more embodiments.

The substrate 300 may be any microelectronic substrate containing silicon, silicon oxide, aluminum, aluminum oxide, tungsten, germanium, combinations therefore, and the like. In certain embodiments, the substrate 300 may be a material such as crystalline silicon (e.g., Si<100> or Si<111>), silicon oxide, strained silicon, silicon germanium, doped or undoped polysilicon, doped or undoped silicon substrates and patterned or non-patterned substrates silicon on insulator (SOI), carbon doped silicon oxides, silicon nitride, doped silicon, germanium, gallium arsenide, glass, sapphire. The substrate may have various dimensions, such as 200 mm, 300 mm, and 450 mm or other diameter substrates, as well as, rectangular or square panels. Unless otherwise noted, embodiments and examples described herein are conducted on substrates with a 200 mm diameter, a 300 mm diameter, or a 450 mm diameter substrate.

In addition to film processing directly on the surface of the substrate 300 itself, in the present disclosure, any of the processing steps disclosed may also be performed on an intermediate layer formed on the substrate 300 (e.g. resist underlayer 302) as disclosed in more detail below, and the term “substrate surface” is intended to include such intermediate layer as the context indicates. Thus, for example, where a film/layer or partial film/layer has been deposited onto a substrate surface, the exposed surface of the newly deposited film/layer becomes the substrate surface.

Methods of the present disclosure provide for forming a precursor termination layer 304 on a resist underlayer 302 disposed on the substrate 300 to facilitate pattern transfer with photoresist pillar structures. The precursor termination layer 304 may modify the surface energy at the interface between the resist underlayer 302 and an overlying patterned EUV photoresist disposed thereon. The substrate 300 may be treated by exposing the resist underlayer 302 to one or more dopant precursors to alter the polarity and/or dispersibility of the surface energy of the resist underlayer 302. The dopants may be thermally activated or reactive using a plasma.

The method 200 begins at operation 210 in which the substrate 300 having the resist underlayer 302, as shown in FIG. 3A, is disposed within a process chamber, such as the process chamber 100 depicted in FIG. 1. The substrate 300 may be the substrate 110 depicted in FIG. 1. In some embodiments, the substrate 300 is positioned within the process chamber 100 with the resist underlayer 302 already formed thereon. In other embodiments, the resist underlayer 302 may be formed on the substrate 300 in the same process chamber 100 prior to performing method 200 to process the resist underlayer 302.

The resist underlayer 302 may be deposited on the substrate 300 using a chemical vapor deposition process (e.g., plasma enabled, plasma pulsed, or thermal) that includes use of activated species (formed from one or more precursors, reactants, and/or inert gases). In some embodiments, a thickness of the resist underlayer 302 formed may be from about 10 Å to about 50 Å.

The substrate 300 (and the resist underlayer 302 disposed thereon) may be positioned on a substrate support, such substrate support 105, in the processing volume 146 of the process chamber 100. For example, the substrate 300 may be positioned on the upper surface 192 of the electrostatic chuck 150. The method 200 may be performed to form the precursor termination layer 304 on the resist underlayer 302 in preparation for performing a EUV lithography process for pattern transfer.

In operation 220, a surface treatment process is performed on the substrate surface to form a precursor termination layer 304 on a top surface of the resist underlayer 302, as shown in FIG. 3B. The surface treatment process includes exposing the substrate surface (e.g., the resist underlayer 302) to a reactive plasma of a treatment gas to treat the substrate surface and form the precursor termination layer 304. The treatment of the substrate surface with reactants from the treatment gas enables modifying the dispersive and/or polar part of the surface energy of the substrate. In some embodiments, the precursor termination layer 304 formed on the substrate surface may have a thickness between about 5 Å and about 100 Å. In some embodiments, the precursor termination layer 304 formed on the substrate surface may have a thickness less than about 10 Å.

In certain embodiments, suitable dopants for treating the substrate surface may be generated from the treatment gas including carbon (C), boron (B), silicon (Si), nitrogen (N), tungsten (W), lead (Pb), tin (Sn), and/or germanium (Ge) containing precursor materials. For example, the resist underlayer gas mixture may comprise dopant precursor gases such as silane, trimethylborane (TMB), diborane (B2H6), phosphine (PH3), arsine (AsH3), and substituted phosphines and arsines, or mixtures thereof. In certain embodiments, the dopant can be thermally activated or activated using a plasma (e.g., a direct or remote plasma) during operation 220.

In certain embodiments, the flow rate of the treatment gas may be at a range from about 2 sccm to 10000 sccm. The dopant precursors may also be carried by a carrier gas, or diluted in a dilution gas, for example helium (He), argon (Ar), nitrogen (N2), hydrogen (H2), or any mixture thereof. In certain embodiments, the flow rate of the dilution gas may be at a range from about 2 sccm to 10000 sccm.

In one embodiment, the reactant or dopant for forming the precursor termination layer 304 is a silicon precursor for forming a silicon termination layer. In such an embodiment, the treatment gas for providing the silicon precursor includes silicon containing gases such as, but not limited to, silane (SiH₄), disilane (Si₂H₆), trisilane (Si₃H₈), dichlorosilane (SiH₂Cl₂), trichlorosilane (SiHCl₃), and silicon tetrachloride (SiCl₄). The surface treatment may also include exposing the substrate surface to additional precursor/inert gases, such as Ar, He, Xe, N₂, N₂O, NH₃, or combinations thereof. The flow rate of the additional process gases may (individually) each be from about 2 sccm to 10000 sccm.

In another embodiment, the reactant or dopant for forming the precursor termination layer 304 is a tin (Sn) precursor for forming a tin termination layer. In such an embodiment, the treatment gas for providing the tin precursor includes tin containing gases such as stannane (SnH₄) gas. The surface treatment may also include exposing the substrate surface to additional precursor/inert gases, such as Ar, He, Xe, N₂, N₂O, NH₃, or combinations thereof. The flow rate of the additional process gases may (individually) each be from about 2 sccm to 10000 sccm.

In a further embodiment, the reactant or dopant for forming the precursor termination layer 304 is a lead (Pb) precursor for forming a lead termination layer. In such an embodiment, the treatment gas for providing the lead precursor includes lead containing gases such as plumbane (PbH₄) gas. The surface treatment may also include exposing the substrate surface to additional precursor/inert gases, such as Ar, He, Xe, N₂, N₂O, NH₃, or combinations thereof. The flow rate of the additional process gases may (individually) each be from about 2 sccm to 10000 sccm.

In some embodiments, the surface treatment of operation 220 can include treatments using one or more hydrocarbon or carbon-containing precursors. The hydrocarbon and/or carbon-containing precursors can be either liquid or gas. In one embodiment, the hydrocarbon precursor has a general formula CₓH_{y}, where x has a range of between 1 and 20 and y has a range of between 1 and 20. In one embodiment, the hydrocarbon compound is an alkane, for example methane (CH₄).

In certain embodiments, various reactants can be generated from combinations of precursor materials including, for example, CH4/N2, CH4/He, N2/He, CH4/Ne, CH4/Ar, CH4/Ne, CH4/Kr, or CH4/Xe. In some embodiments, the treatment gas may further include an inert gas, a dilution gas, a nitrogen-containing gas, or combinations thereof. In some embodiments, the treatment gas is vapor at room temperature, which simplifies the hardware for material metering, control and delivery to the process chamber 100.

During the surface treatment process of operation 220, several processing parameters are generally regulated to control and tune the surface treatment process. For example, the reactive plasma formed from the treatment gas may be an RF plasma generated by capacitive or inductive means, and may be energized by coupling RF power into the treatment gas provided to the process chamber. The RF power may be a dual-frequency RF power that has a high frequency component (e.g., 13.6 MHz) and a low frequency (e.g., 2 KHz) component. The RF plasma may be formed by coupling the RF power at a suitable frequency to the aforementioned treatment gas to establish and maintain the RF plasma. In some embodiments, about 0 watts to about 10,000 watts of RF power at a frequency in a range from about 2 MHz to about 162 MHz, having continuous wave or pulsing capabilities, may be provided to ignite and maintain the reactive plasma.

During operation 220, the substrate 300 may be maintained at a temperature between about 0 degrees Celsius and about 600 degrees Celsius (e.g., between about 200 degrees Celsius to about 600 degrees Celsius; or between about 500 degrees Celsius to about 600 degrees Celsius). The pressure in the process chamber may generally range from about 0.3 Torr to about 30 Torr (e.g., between about 1 Torr and about 20 Torr; or between about 5 Torr and about 10 Torr).

In another example, the surface treatment process of operation 220 may include treating the substrate surface with reactive radicals. The reactive radicals may be radical species and filtered out from a plasma. The reactive radicals may include, but are not limited to, one or more of carbon (C), boron (B), silicon (Si), nitrogen (N), tungsten (W), lead (Pb), tin (Sn), and germanium (Ge). The reactive radicals are generally supplied by an RPS, such as a CCP source, or any other suitable source. By exposing the substrate surface to reactive radicals, the substrate surface is modified to contain the precursor termination layer 304, which causes enhanced adhesion with the overlying photoresist, and thus, minimizing the risk of pattern collapse after or during patterning of the photoresist.

After the precursor termination layer 304 is formed on the substrate surface, in operation 230, a EUV photoresist film 306 can be formed over the precursor termination layer 304. The EUV photoresist film 306 comprises suitable photosensitive resist material suitable for exposure by EUV energy. In some embodiments, the EUV photoresist film 306 is a metal oxide photoresist. In other embodiments, the EUV photoresist film 306 is a chemically amplified photoresist. The EUV photoresist film 306 can be a positive resist that becomes soluble upon exposure to EUV radiation, or a negative resist that becomes insoluble upon exposure to EUV radiation. The EUV photoresist film 306 may have a thickness ranging from between about 100 nm and about 1000 nm.

In operation 240, the EUV photoresist film 306 is patterned to form a EUV patterned photoresist 308, as shown in FIG. 3D. The photoresist film 306 may be patterned with any suitable method. In some embodiments, patterning the EUV photoresist film 306 comprises exposing the photoresist film 306 to EUV radiation and developing the exposed photoresist film 306 to form the patterned photoresist 308. In some embodiments, the precursor termination layer 304 assist in providing for a decreased DTS ratio when the EUV photoresist film 306 is exposed to EUV radiation when patterning the EUV photoresist film 306 in operation 240. In some embodiments, the EUV photoresist film 306 may be exposed to a dose of EUV radiation comprising a DTS ratio from about 1 mJ/cm² to about 100 mJ/cm². In certain embodiments, the DTS ratio is less than 100 mJ/cm², such as less than 80 mJ/cm², such as less than 50 mJ/cm², such as less than 40 mJ/cm². In some embodiments, the exposed photoresist film 306 may be developed using a wet development process to form the patterned photoresist 308.

In some embodiments, as shown in FIG. 3D, the EUV photoresist film 306 is patterned such that the EUV patterned photoresist 308 comprises a plurality of cylindrical pillar structures or nano-pillars. In some embodiments, the EUV patterned photoresist 308 may be patterned to form an array of pillar structures or nano-pillars. As compared to photoresist patterned to form line and space features, photoresist pillar structures generally have a smaller contact area with the substrate surface and are also structurally weaker. As such, photoresist pillar structures are generally more aggressive in terms of reliance on surface adhesion forces such that conventional resist adhesion forces often may not be sufficient to avoid pattern collapse. Other shaped patterned photoresist structures may also benefit from the present disclosure. In general, photoresist films patterned to form high aspect ratio structures regardless of perimeter shape (e.g., circular for nano-pillars) are similarly also aggressively reliant on surface adhesion forces to prevent pattern collapse. In some embodiments, the EUV patterned photoresist 308 may be patterned to form other column shaped structures, such as prismatic column structures or hexagonal shaped column structures.

Methods provided herein therefore facilitate improving adhesion of patterned photoresist pillar structures to the substrate surface using a surface termination layer at the interface between the substrate surface and the pillar patterned photoresist. In addition to minimizing the risk of pattern collapse, advantages of the present disclosure also provides for increased depth of focus, increased process window (area with no pattern collapse) of the substrate surface, extended resolution limit/minimum CD of the pillar patterned photoresist without comprising CD uniformity, and improved sensitivity (DTS ratio).

The following non-limiting examples are provided to further illustrate embodiments described herein. However, the examples are not intended to be all inclusive and are not intended to limit the scope of the embodiments described herein.

In one example, a resist underlayer was formed on a spin on glass substrate and treated using silane gas in accordance with the methods discussed above to form a silicon termination on the substrate surface. A second substrate with the same resist underlayer was also formed but received no surface treatment for use as a reference. A EUV spin on metal photoresist was then formed on the resist underlayer of each of the substrates and patterned to form an array of pillar structures with a 40 nm pitch. The patterning of the photoresist included exposing the metal photoresist to EUV radiation, wet developing the photoresist with a chemical developer solution (e.g., Tetramethylammonium hydroxide (TMAH) 2.38% solution), and drying the photoresist. When the resist underlayer was not treated, pattern collapse of the photoresist pillar structures was observed with only a 23 nm minimum CD being achieved. In contrast, as compared to the patterned photoresist formed on the substrate with the treated resist underlayer and silicon termination layer, treatment to form the silicon termination layer on the resist underlayer improved the minimum CD achieved to 18 nm, less than half the 40 nm pitch of the photoresist pillar structures.

In summary, advantages and benefits of the present disclosure provide a process for treating a resist underlayer to form a precursor termination layer for improving adhesion force at the resist-substrate interface of photoresist films patterned to form high aspect ratio structures, such as cylindrical pillars or nano-pillars. In some embodiments described herein, the resist underlayer may be treated to form a silicon termination layer on the substrate surface to improve adhesion force at the resist-substrate interface. In other embodiments, termination layers with other dopants such as nitrogen (N), fluorine (F), iodine (I), oxygen (O), boron (B), tungsten (W), tin (Sn), lead (Pb), or germanium (Ge) may be used to form the precursor termination layer on the substrate surface. The precursor termination layer alters the interfacial surface energy on the substrate surface to improve adhesion force at the resist-substrate interface. Without being bound by theory, such improvements in the adhesion force is significant and sufficient for photoresists patterned to form tall high aspect ratio structures that are generally more susceptible to pattern collapse.

While the foregoing is directed to embodiments of the present disclosure, other and further embodiments of the disclosure may be devised without departing from the basic scope thereof, and the scope thereof is determined by the claims that follow.

What is claimed is:

1. A method of processing a substrate, comprising:
disposing a substrate on a substrate support in a processing volume of a process chamber;
performing a vapor deposition process to form a resist underlayer on a top surface of the substrate;
performing a surface treatment process to form a precursor termination layer on the resist underlayer;
forming a photoresist film on the precursor termination layer; and
patterning the photoresist film to form a patterned photoresist with a wet chemical process, the patterned photoresist comprising a plurality of high aspect ratio photoresist structures.

2. The method of claim 1, wherein the surface treatment process comprises flowing a treatment gas into the processing volume to expose the resist underlayer to the treatment gas, and applying a RF bias to the processing volume to generate a plasma of the treatment gas for forming the precursor termination layer.

3. The method of claim 2, wherein the treatment gas comprises a dopant precursor comprising nitrogen (N), fluorine (F), iodine (I), oxygen (O), silicon (Si), boron (B), tungsten (W), tin (Sn), lead (Pb), germanium (Ge), or mixtures thereof.

4. The method of claim 2, wherein the treatment gas comprises a hydrocarbon precursor comprising a general formula CₓH_{y}, where x has a range of between 1 and 20 and y has a range of between 1 and 20.

5. The method of claim 2, wherein the RF bias is provided at a power between about 10 Watts and about 3000 Watts, and at a frequency of between about 200 KHz to about 80 MHz.

6. The method of claim 2, wherein the treatment gas further comprises a dilution gas comprising He, Ar, Xe, H₂, or combinations thereof.

7. The method of claim 1, wherein the surface treatment process comprises flowing a silane gas into the processing volume, and applying a RF bias to the processing volume to form a silicon termination layer on the resist underlayer.

8. The method of claim 1, wherein the surface treatment process comprises maintaining the processing volume at a pressure between about 0.1 mTorr and about 100 Torr.

9. The method of claim 1, wherein the surface treatment process comprises maintaining the processing volume at a temperature between about 10 degrees Celsius and about 600 degrees Celsius.

10. The method of claim 1, wherein patterning the photoresist film comprises exposing the photoresist film to EUV radiation and developing the exposed photoresist film with a wet development and cleaning process.

11. The method of claim 1, wherein the patterned photoresist comprises a plurality of photoresist pillar structures.

12. The method of claim 1, wherein the precursor termination layer comprises a thickness less than about 10 Å.

13. The method of claim 1, wherein the surface treatment process comprises flowing a stannane gas into the processing volume, and applying a RF bias to the processing volume to form a tin termination layer on the resist underlayer.

14. The method of claim 1, wherein the surface treatment process comprises flowing a plumbane gas into the processing volume, and applying a RF bias to the processing volume to form a lead termination layer on the resist underlayer.

15. A method of processing a substrate, comprising:
flowing a treatment gas into the processing volume to expose a resist underlayer disposed on a substrate to the treatment gas;
applying a RF bias to the processing volume to generate a plasma of the treatment gas to treat the resist underlayer and form a precursor termination layer on a top surface of the resist underlayer, the precursor termination layer comprising a thickness less than about 10 Å;
forming a photoresist film on the precursor termination layer;
exposing the photoresist film to EUV radiation; and
developing the photoresist film with a wet chemical process to form a patterned photoresist comprising a plurality of high aspect ratio photoresist structures.

16. The method of claim 14, wherein the treatment gas comprises a dopant precursor comprising nitrogen (N), fluorine (F), iodine (I), oxygen (O), silicon (Si), boron (B), tungsten (W), tin (Sn), lead (Pb), germanium (Ge), or mixtures thereof.

17. The method of claim 14, wherein the patterned photoresist comprises a critical dimension of less than about 20 nm.

18. A method of processing a substrate, comprising:
disposing a substrate on a substrate support in a processing volume of a process chamber;
performing a chemical vapor deposition process to form a resist underlayer on a top surface of the substrate;
flowing a treatment gas into the processing volume;
applying a RF bias to the processing volume to generate a plasma from the treatment gas and form a precursor termination layer on a top surface of the resist underlayer, the precursor termination layer comprising a thickness less than about 10 Å;
forming a EUV photoresist film on the precursor termination layer; and
performing a EUV lithography process to pattern the photoresist film and form a patterned photoresist, the patterned photoresist comprising a plurality of high aspect ratio photoresist structures and a critical dimension of less than about 20 nm.

19. The method of claim 18, wherein the treatment gas comprises a dopant precursor comprising nitrogen (N), fluorine (F), iodine (I), oxygen (O), silicon (Si), boron (B), tungsten (W), tin (Sn), lead (Pb), germanium (Ge), or mixtures thereof.

20. The method of claim 18, wherein performing the EUV lithography process comprises:
exposing the EUV photoresist to EUV radiation;
wet developing the EUV photoresist with a chemical developer solution; and
drying the EUV photoresist.
